(19) United States
(12) Patent Application Publication
(10) Pub. No.: US 2010/0070212 A1
(43) Pub. Date: Mar. 18, 2010

(54) Method and apparatus for determining state of inverter capacitor in an electric drive

(75) Inventor: Johsua Williams, Peoria, IL (US)

Correspondence Address: LEYDIG, VOIT & MAYER, LTD, TWO PRUDENTIAL PLAZA SUITE 4900, 180 N. STETSON AVE, CHICAGO, IL, 60601, US

(73) Assignee: Caterpillar Inc., Peoria, IL (US)

(21) Appl. No.: 12/210,883

(22) Filed: Sep. 15, 2008

(51) Int. Cl. G06F 19/00; G01R 31/12

(52) U.S. Cl. 702/58; 324/548

(57) ABSTRACT

A method of inverter capacitance diagnosis for detecting an imminent failure of one or more inverter capacitors in an electric power supply system for a machine detects that the generator has ceased generating electrical power takes a plurality of current samples on the DC link between predetermined voltage points. The plurality of current samples are integrated as a function of time to create a discharge integral, which is compared to a previously obtained discharge integral if available. The process sets a diagnostic flag to indicate an imminent failure of the one or more inverter capacitors if the discharge integral varies from the previously obtained discharge integral by more than a predetermined value.

### TECHNICAL FIELD

This patent disclosure relates generally to testing electrical systems and components within a machine and, more particularly to a method and apparatus for determining the state of an inverter capacitor associated with an electric drive system.

### BACKGROUND

Heavy machinery, such as off-highway trucking equipment, is commonly used in mining, heavy construction, quarrying, and other applications. Due to the substantial capital investment involved, tight tolerances with respect to the time allotted for completing tasks, and the expense of maintaining and operating heavy machinery, such as a mining truck, an entity can suffer significant monetary losses when the heavy machinery malfunctions. The complexity of modern heavy machinery often exacerbates this problem due to the need for skilled personnel to perform various tests on such machinery to trouble shoot malfunctions. Even when skilled personnel are employed to locate and address problems, significant time and money may be spent before the machine is again functional.

One advance that has improved efficiency associated with the use of heavy machinery is the adoption of Alternating Current (AC) electric drive systems. Electric drive systems typically require less maintenance and thus, have lower life cycle costs. Still, when the machinery malfunctions, the costs associated with finding the fault and effecting a suitable repair are often substantial.

Electric drive systems for machines typically include a power circuit that selectively activates one or more drive motors at a desired torque. Each of the drive motors is connected to a wheel or other traction device that operates to propel the machine. A hybrid drive system includes a prime mover, for example, an internal combustion engine, that drives a generator (synonymously referred to herein as a “power generator”). The generator produces electrical power that is conditioned and ultimately used to drive the motors. Conceptually, as the machine is propelled, the mechanical power produced by the engine is converted to electrical power by the generator. This electrical power is processed and is metered to the motors. The motors transform the electrical power back into mechanical power that drives the wheels and propels the machine.

One fault that can be difficult to detect in a timely fashion, but one that can have a significant impact on the operation of the drive system, is a failure of one or more inverter capacitors employed to filter a DC link voltage. Such capacitors are large and robust, and cannot easily be checked due to their location. As the capacitors fail, they present one of a number of failure modes including a short mode and an open circuit mode. In the first mode, the short-circuited capacitor shorts or partially shorts the DC link, rendering the drive system inoperable. In the second mode, the failed capacitor is effectively removed from the circuit, causing the DC link voltage become irregular. In either case, failure to timely detect a capacitor failure can complicate and prolong the course of repair, and may also cause other machine components to be damaged.

### SUMMARY

The disclosure describes, in one aspect, a method of inverter capacitor diagnosis for detecting an imminent failure of one or more inverter capacitors in an electric power supply system for a machine. The machine has a prime mover and a generator receiving power from the prime mover to produce electrical power. The electrical power is processed and made available on a DC link. Initially, the process, which may be executed by a controller or otherwise, detects that the generator has ceased generating electrical power. In response to detecting that the generator has ceased generating electrical power, the electronic controller waits until a first voltage V₁ is reached on the DC link and then takes a series of samples of the DC link current until a second voltage V₂ is reached. The series of samples is then integrated over time to create a discharge integral.

The discharge integral is compared with a prior discharge integral generated on the prior shut down cycle of the machine. In an embodiment, the discharge integral is compared with an average or other compilation of prior discharge integrals. If discharge integral varies from the prior discharge integral by more than a predetermined acceptable amount then the process sets a diagnostic flag to indicate that failure of one or more capacitors may be imminent.

### BRIEF DESCRIPTION OF THE DRAWINGS

FIG. 1 is a front view of a machine in accordance with the disclosure:

FIG. 2 is a side view of a machine in accordance with the disclosure:

FIG. 3 is a block diagram representation of a direct series electric drive system for a machine in accordance with the disclosure;

FIG. 4 is another block diagram representation of a drive system in which the disclosure may be deployed;

FIG. 5 is a simplified electrical circuit diagram for the power circuit used in the drive system shown in FIG. 4;

FIG. 6 is a block diagram illustrating various connections between a controller and various components of an electric drive system in accordance with the disclosure;

FIG. 7 is a simplified schematic and nodal diagram of a capacitance system for filtering a DC link voltage;

FIG. 8 is a timing diagram showing the discharge current curve of the capacitance system of FIG. 8; and

FIG. 9 is a flow chart illustrating a process of inverter capacitor diagnosis in accordance with the disclosed principles.

### DETAILED DESCRIPTION

This disclosure relates to systems and methods for determining an operating condition of an inverter capacitor in an electric drive machine. The disclosure that follows uses an example of a direct series electric drive system having an engine connected to a generator for producing electrical power that propels the machine. In the exemplary embodiments presented, the generator associated with the machine is a multi-phase alternating current (AC) synchronous brushless generator having a rotating input coupled with the output of the engine. The generator includes a rotating rectifier assembly using a wye (Y) configuration for the windings. The systems and methods disclosed herein, however, also have applicability to other electric drive vehicles. For example, the generator associated with the machine or vehicle could use a delta (A) configuration for the windings.

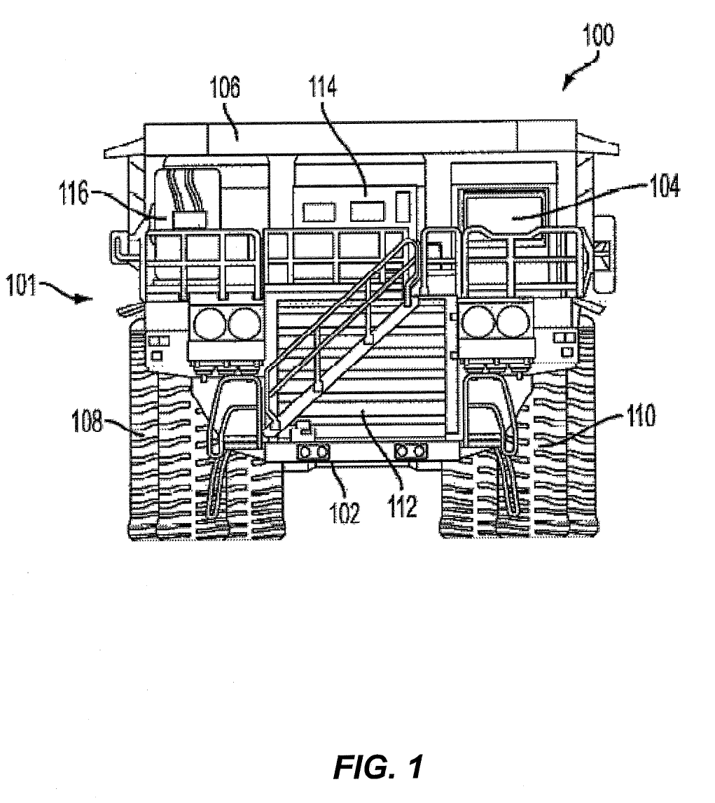

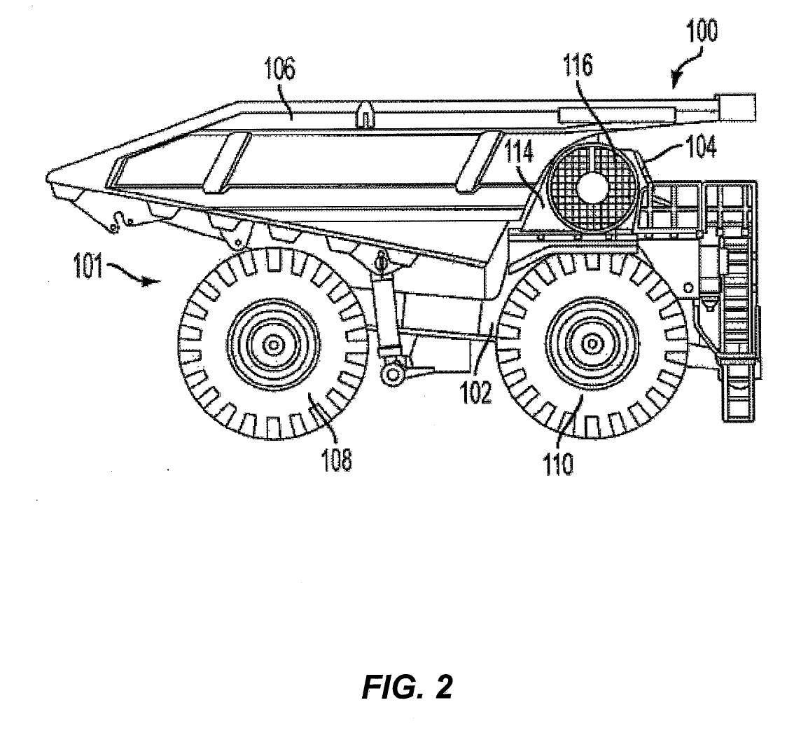

FIG. 1 and FIG. 2 illustrate, respectively, a front and a side view of a machine 100. The machine 100 has a direct series electric drive system. One example of the machine 100 is an off-highway truck 101 such as those used for construction, mining, or quarrying. In the description that follows, this example illustrates the various arrangements that can be used on machines having direct series electric drive system systems. As will be appreciated, any other vehicle having a direct series drive, electric-only, or direct series electric drive arrangement can benefit from the advantages described herein. The term “machine,” therefore, is used to generically describe any machine having at least one drive wheel that is driven by a motor connected to the wheel. Electrical power may be generated onboard by a generator, alternator, or other power-generation device, which may be driven by an engine or other prime mover. Alternatively, electrical power may be stored but not generated on-board.

A front view of the off-highway truck 101 is shown in FIG. 1, and a side view is shown in FIG. 2. The off-highway truck 101 includes a chassis 102 that supports an operator cab 104 and a bucket 106. The bucket 106 is pivotally connected to the chassis 102 and is arranged to carry a payload when the off-highway truck 101 is in service. An operator occupying the operator cab 104 can control the motion and the various functions of the off-highway truck 101. The chassis 102 supports various drive system components. These drive system components are capable of driving a set of drive wheels 108 to propel the off-highway truck 101. A set of idle wheels 110 can steer such that the off-highway truck 101 can move in any direction. Even though the off-highway truck 101 includes a rigid chassis with powered wheels for motion and steerable wheels for steering, one can appreciate that other machine configurations can be used. For example, such configurations may include articulated chassis with one or more driven wheels.

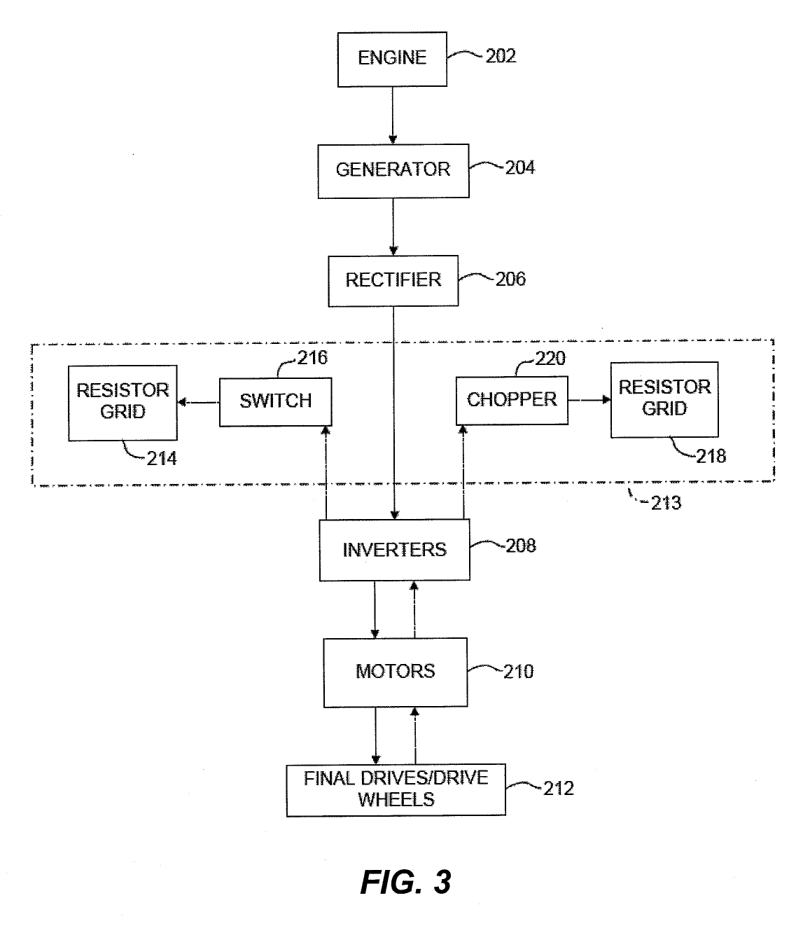

The off-highway truck 101 employs a direct series electric drive system, which in this instance refers to the use of more than one source or form of power to drive the drive wheels 108. A block diagram for the direct series electric drive system of the machine 100, for example, the off-highway truck 101, is shown in FIG. 3. In the block diagram, the flow of power in the system when the machine is propelled is denoted by solid-lined arrows. Conversely, the flow of power during a retarding mode is shown in dash-lined arrows.

The direct series electric drive system includes an engine 202, for example, an internal combustion engine such as a diesel engine, which produces an output torque at an output shaft (not shown). The output shaft of the engine 202 is connected to a generator 204. During operation, the output shaft of the engine 202 rotates a rotor of the generator 204 to produce electrical power, e.g., in the form of AC power. This electrical power is supplied to a rectifier 206 and converted to DC power. The rectified DC power may be converted again to AC power by an inverter circuit 208.

The inverter circuit 208 may be capable of selectively adjusting the frequency and/or pulse-width of its output, such that motors 210, connected to an output of the inverter circuit 208, may be operated at variable speeds. The motors 210 may be connected via final assemblies (not shown) or directly to drive wheels 212 of the machine 100.

When the off-highway truck 101 is propelled, the engine 202 generates mechanical power that is transformed into electrical power, which is conditioned by various electrical components. In an illustrated embodiment, such components are housed within a cabinet 114 (FIG. 1). The cabinet 114 is disposed on a platform that is adjacent to the operator cab 104 and may include the rectifier 206 (FIG. 3), inverter circuit 208 (FIG. 3), and/or other components. When the off-highway truck 101 is to be decelerated or its motion is otherwise to be retarded, for example, to prevent acceleration of the machine when traveling down an incline, its kinetic energy is converted to electrical energy. Effective disposition of this generated electrical power enables effective retarding of the off-highway truck 101. Other brakes such as friction brakes may be used for additional braking and/or for supplying braking power when the machine is stationary.

When the machine 200 is retarding, the kinetic energy of the machine 200 is transferred into rotational power of the drive wheels that rotates the motors 210, which act as electrical generators. The electrical power generated by the motors 210 has an AC waveform. Because the inverter circuit 208 is a bridge inverter, power supplied by the motors 210 is rectified by the inverter circuit 208 into DC power. Dissipation of the DC power generated by the motors 210 produces a counter-rotational torque at the drive wheels 108 to decelerate the machine. Dissipation of this DC power may be accomplished by passing the generated current rectified by the inverter circuit 208 through a resistance. To accomplish this, a retarder arrangement 213 is used. The retarder arrangement 213 includes a first resistor grid 214 that is arranged to receive current from the inverter circuit 208 via a switch 216. Excess electrical power is also dissipated as heat as it passes through a second resistor grid 218, which is arranged to receive electrical power via a chopper circuit 220. The chopper circuit 220 operates to selectively route a portion of the developed electrical power through the second resistor grid 218. One embodiment for the drive and retard system is described in more detail below.

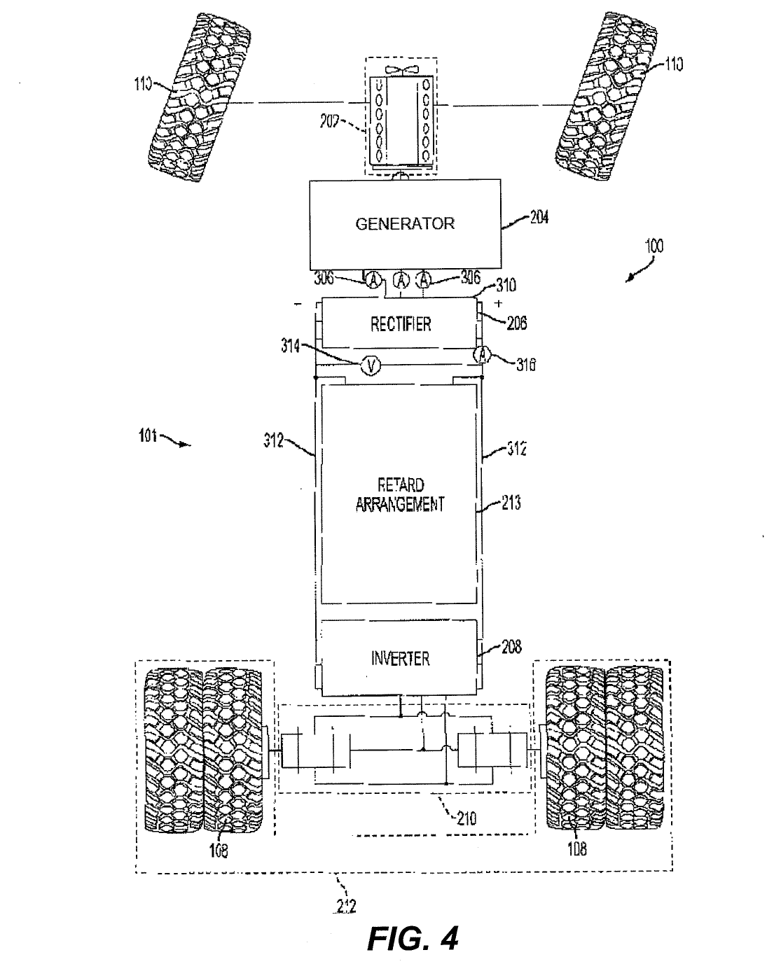

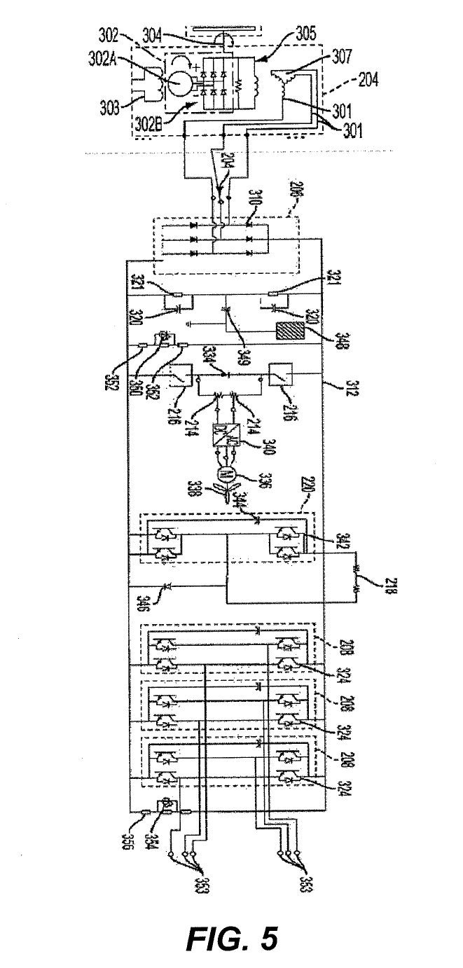

A block diagram of the direct series electric drive system of the off-highway truck 101, as one example for the machine 100, is shown in FIG. 4 and FIG. 5. In these views, like reference numerals are used to designate like elements for the sake of simplicity. Further, the block diagram of FIG. 5 includes a particular embodiment with component examples that can be included in the functional blocks shown in FIG. 4. Hence, the block diagrams shown in FIG. 4 and FIG. 5 should be referred to together when considering the description that follows.

As shown, the engine 202 is connected to the generator 204 (shown in FIG. 4) via an output drive shaft 304. Even though a direct connection to the output drive shaft 304 is shown, other drive components, such as a transmission or other gear arrangements, may be utilized to couple the output of the engine 202 to the generator 204. The generator 204 may be any appropriate type of generator or alternator known in the power generation art.

In one embodiment, the generator 204 comprises a three-phase AC synchronous generator having a brushless wound rotor. The generator 204 has an output 301 for each of the three phases of alternating current being generated, with each output having a respective current transducer 306 connected thereto. The rotor of the generator 204 (shown in FIG. 4) includes a rotating rectifier 302 that is connected to a rotating exciter armature 302A. The rotating exciter armature 302A is energized by an excitation field produced by an excitation winding 303. Thus, the application of an excitation signal at the input to the excitation winding 303 creates an excitation field to activate the generator field 305. The generator field 305, in turn, produces the output available at three leads of the armature 307 of the generator 204. In the illustrated embodiment, the rotating rectifier 302 includes a rotating exciter armature 302A that is connected to an array of rotating diodes 302B. The current outputs of the generator 204, which are collectively considered the output of the generator 204, are connected to a rectifier 206.

The rectifier 206 converts the AC power supplied by the generator 204 into DC power. Any type of rectifier 206 may be used. The rectifier 206 converts the AC power supplied by the generator 204 into DC power. Any type of rectifier 206 may be used. In the example shown, the rectifier 206 is a poly-phase diode bridge, and in particular is a three phase full bridge rectifier 206. The illustrated rectifier 206 includes three parallel pairs of power diodes 310, each pair being associated with a given phase of the output of the generator 204. Each such diode pair includes two power diodes 310 connected in series across the DC link 312, with the selected output of the generator 204 providing a power input between each pair.

When power is supplied from the output of the three phase generator 204, the rectifier 206 operates to provide full wave rectification of each of the phases of the three-phase alternating current. The rectifier 206 develops a voltage across a DC linkage or DC link 312. This DC link voltage is available at a first rail and a second rail of the DC link 312. The first rail is typically at a first voltage and the second rail is typically at a second voltage during operation. Either of the first and second voltages may be zero. During operation, a voltage is developed across the first and second rails of the DC link 312 by the inverter circuit 208.

One or more capacitors 320 are connected in parallel with one or more resistors 321 across the DC link 312 to smooth the voltage V across the first and second rails of the DC link 312. The voltage V across the DC link 312 is measured by a voltage transducer 314, while the current A supplied by the DC link 312 is measured by a current transducer 316, as shown in FIG. 4.

The inverter circuit 208 is connected in parallel with the rectifier 206 and operates to transform the DC voltage V into variable frequency sinusoidal or non-sinusoidal AC power that drives, in this example, two drive motors 210 (FIG. 4). Any known inverter may be used for the arrangement of the inverter circuit 208. In the example shown in FIG. 5, the inverter circuit 208 includes three phase arrays of insulated-gate bipolar transistors (IGBT) 324 that are arranged in transistor pairs and that are configured to supply a 3-phase AC output to each drive motor 210.

The inverter circuit 208 can control the speed of the motors 210 by controlling the frequency and/or the pulse-width of the AC output. The drive motors 210 may be directly connected to the drive wheels 108 or may power the final drives that power the drive wheels 212. Final drives, as is known, operate to reduce the rate of rotation and increase the torque between each drive motor 210 and each set of drive wheels 212.

In alternative embodiments, the engine 202 and generator 204 are not required to supply the power necessary to drive the drive motors 210. Instead, such alternative embodiments use another source of power, such as a battery or contact with an electrified rail or cable. In some embodiments, one drive motor 210 may be used to power all drive wheels of the machine, while in other embodiments, any number of drive motors may be used to power any number of drive wheels, including all wheels connected to the machine.

Returning now to the block diagrams of FIG. 4 and FIG. 5, when the machine 100 operates in an electric braking mode, which is also known as electric retarding, rotation of the drive wheels 108 will power the drive motors 210 which, in this mode, act as generators by producing AC power, thus retarding the machine. The generated AC electrical power can be converted into DC electrical power through the inverter circuit 208. A retarder arrangement 213 can include any suitable arrangement that will operate to dissipate electrical power during retarding of the machine. In the exemplary embodiments shown in FIG. 5, the retarder arrangement 213 includes a first resistor grid 214 arranged to dissipate electrical energy at a fixed rate. The retarder arrangement 213 may also include a second resistor grid 218, to which DC current is supplied via a chopper circuit 220. When the machine 100 is being propelled, the first resistor grid 214 is electrically isolated from the DC link 312 by two contactors or bipolar automatic switches (BAS) 216. A diode 334 is disposed in parallel to the first resistor grid 214 to reduce arcing across the BAS 216, which also electrically isolate the first resistor grid 214 from the DC link 312 during a propel mode of operation. Blower 338, driven by a motor 336, operates to convectively cool the first resistor grid 214. An AC/DC converter 340 draws power from voltage-regulated locations across a portion of the first resistor grid 214.

The embodiment for a drive system shown in FIG. 5 includes other components that are discussed for the sake of completeness. Such optional components are shown because they promote smooth and efficient operation of the drive system. In this exemplary embodiment, a leakage detector 348 is connected between the two resistors 321, in series with a capacitor 349, to the first and second rails of the DC link 312. The leakage detector 348 detects any current leakage to ground from either of the first and second rails of the DC link 312. Further, in one embodiment, a first voltage indicator 350 may be connected between resistors 352 across the first and second rails of the DC link 312. The first voltage indicator 350 may be disposed between the rectifier 206 and the retarder arrangement 213 such that a high voltage condition may be detected. In a similar fashion, a second voltage indicator 354 may be connected between resistors 356 across the first and second rails of the DC link 312. The second voltage indicator 354 may be disposed between connection nodes 353 that connect to the drive motors 210 and the inverter circuit 208 to detect a voltage condition occurring during, for example, a bus bar fracture where the DC link 312 is not continuous, in order to diagnose whether the inverter circuit 208 is operating.

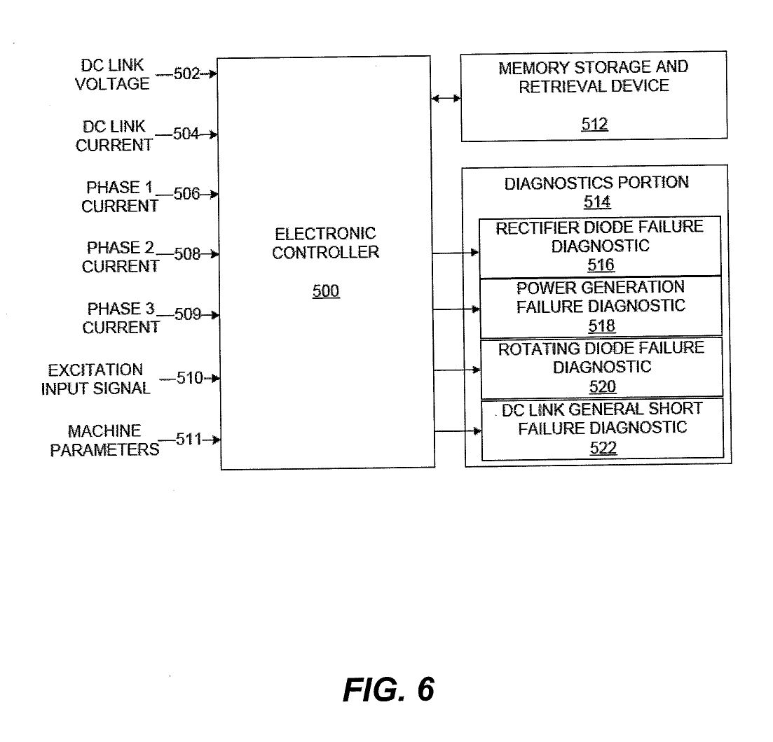

A block diagram for an electronic controller for use in the drive system of an electric drive machine is shown in FIG. 6. The electronic controller may be a single controller or may include more than one controller disposed to control various functions and/or features of a machine. For example, a master controller, used to control the overall operation and function of the machine, may be cooperatively implemented with a motor or engine controller used to control the engine 202. In this embodiment, the term “controller” is meant to include one, two, or more controllers associated with the machine 100 that cooperate in controlling various functions and operations of the machine 100 (FIG. 1). The functionality of the controller, while shown conceptually in FIG. 6 to include various discrete functions for illustrative purposes only, may be implemented in hardware and/or software without regard to the discrete functionality shown. Accordingly, various interfaces of the controller are described relative to components of the drive system shown in the block diagram of FIG. 4. Such interfaces are not intended to limit the type and number of components that are connected, nor the number of controllers that are described.

In FIG. 6, a controller 500, which can be an electronic controller, is disposed to receive a voltage signal provided at a node 502, which voltage signal is indicative of the instantaneous DC voltage present at the DC link 312 (FIG. 4). The voltage transducer 314, for example, measures this value. In a similar fashion, the controller 500 receives a current signal provided at a second node 504, which is indicative of the current passing through the DC link 312 (FIG. 4). The current transducer 316 (see FIG. 4), for example, measures this value. Additionally, the controller 500 is disposed to receive three phase current signals provided, one each, at a third node 506, a fourth node 508, and a fifth node 509, respectively. The current transducers 306, for example, may each measure these values. In one embodiment, the three phase current signals provided may have an adequately small resolution such that the current transducers used to measure such currents may have a relatively quick response time, for example, a resolution of a few milliseconds. Such resolution can enable the electronic controller 500 to discern the magnitudes of the currents passing through each of the three outputs 301 of the generator 204 (FIG. 5). In addition, the controller 500 may be capable of discerning the waveform shape. For example, each of the waveforms may be expected to have a sinusoidal waveform in each of the current signals. Based on such data, the controller 500 may determine the instantaneous phase angle of each of the three currents during operation.

The controller 500 may further receive information concerning the operation of the electric drive system of the machine 100. For example, in the embodiment of FIG. 5, the generator 204 operates under the control of an excitation signal applied to the excitation winding 303. The controller 500 may monitor the excitation signal applied to the excitation winding 303 at a sixth node 510. The electronic controller 500 may also receive information indicative of engine operating parameters. Such engine parameters may include engine speed, engine load, torque output, the presence of engine faults, or other parameters that concern the operating state of the engine. Such engine parameters may be available for the electronic controller at a seventh node 511.

The electronic controller 500 may operate in a logical fashion to perform operations, execute control algorithms, store and retrieve data, and so forth. In this embodiment, the electronic controller 500 may access a memory storage and retrieval device 512 that contains, for example, one or more tables (or other appropriate data organization) containing addressable elements of data. The memory storage and retrieval device 512 may be in the form of read only memory (ROM) or random access memory (RAM) or integrated circuitry that is accessible by the electronic controller 500 or integrated therewith.

In addition to its function of controlling various components and/or systems of the machine 100, the electronic controller 500 may further be disposed to diagnose fault conditions of various components and systems. More specifically, the electronic controller 500 may continuously monitor various operating parameters of the machine 100, compare them to respective expected values, and diagnose failures or fault conditions in various systems of the machine when the monitored parameters, or sets of parameters, diverge from expected values. In one embodiment, the electronic controller 500 may perform diagnostic operations when the machine is first started, or idle, such that various operating parameters are repeatable and stable. For example, various diagnostic operations may be performed when the electric drive system of the machine is operating and in an idle condition. An idle condition is meant to encompass any operating mode of the machine during which generator is operating but there is no power or very little electrical power being consumed. In such a condition, fault conditions may be detected by the electronic controller 500 and stored within the memory storage and retrieval device 512 for later retrieval and inspection by service personnel. These fault indications may be in the form of single bit data elements that, for example, are set at a zero value when no fault has been detected, and changed to a value of one when a fault has been detected. Other data values or variable types may also be used.

In one embodiment, the electronic controller 500 may include a register of diagnostic codes or a diagnostics portion 514. The diagnostics portion 514 includes a plurality of fault flags corresponding to certain malfunction or fault conditions detected by the electronic controller 500. These fault flags may include a rectifier diode failure diagnostic flag 516, a power generation failure diagnostic flag 518, a rotating diode diagnostic failure diagnostic flag 520, a DC link general short failure diagnostic flag 522, and others. These failure diagnostic flags 516, 518, 520, and 522, may represent values that may be selectively changed by one or more control algorithms operating within the electronic controller 500 and whose values may be stored in the RAM of the electronic controller 500 for later retrieval or inspection by service personnel.

As noted above, the one or more capacitors 320 are important to the functioning of the machine, in that they filter the DC link voltage. A partial failure in this system, which usually indicates an imminent total failure, can be difficult to detect in a timely fashion. The capacitors 320 are difficult to check with any regularity due to their location and the need to isolate them for testing. Unfortunately, failure to timely detect a capacitor breakdown can complicate and prolong the course of repair, and may also cause other systems and components to be damaged.

Thus, in an aspect of the disclosed principles, a self-test mode is enabled which allows the machine to self-diagnose a change in the capacitance of the filter capacitance system without removing the elements of the system and without requiring user intervention. Moreover, the disclosed technique functions regardless of the magnitude of the resistor grid load existing in parallel with the filter capacitance system.

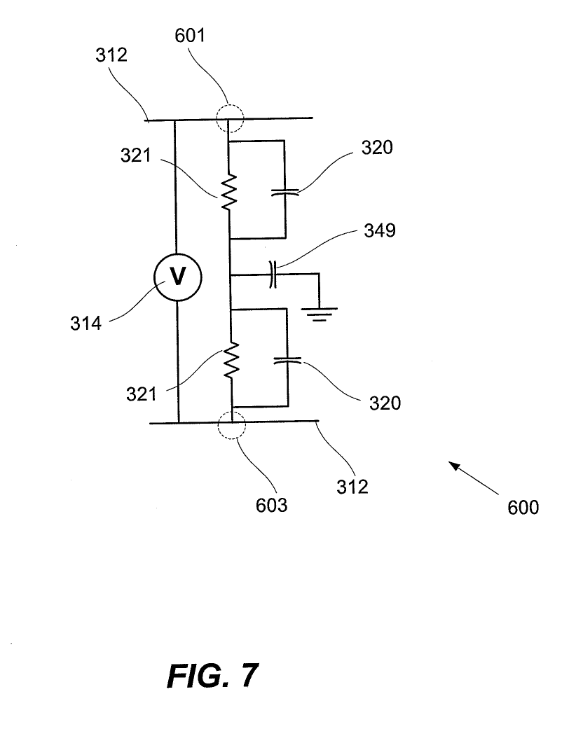

FIG. 7 is a simplified schematic and nodal diagram of an exemplary inverter capacitance system 600 for filtering the DC link voltage as in the system of FIG. 4. In the illustrated arrangement, voltage transducer 314 is disposed across the DC link 312 in order to measure the available voltage. It will be appreciated that the voltage V across the DC link 312 will be, on average, a substantial value, e.g., 2 kV, during operation. It will be appreciated that the voltage V across the DC link 312 will be essentially zero when the generator 204 is not operating, after the DC link 312 has been discharged through one or more resistor grids.

Beginning with the state in which the generator 204 is operating normally, the voltage transducer 314 will produce a sensor signal indicative of the operating voltage. In this condition, the first node 601 and the second node 603 will exhibit a potential difference equal to the operating voltage. Assuming that the one or more resistors 321 are of substantially equal value, the node that is tapped to capacitor 349 will be at a potential difference halfway between the first node 601 and the second node 603. Thus, the potential difference across each half of the filter capacitance system 600 will be one-half of the total operating voltage (½V).

Given this operational state, each resistor 321 and each capacitor 320 exhibits a potential voltage drop of ½V. For each resistor 321, this voltage drop is represented by a current flow of V/2R. For each capacitor 320, this voltage drop is represented by zero current flow and a steady-state voltage across the capacitor plates of ½V. Thus, during operation of the machine, the capacitor plates of the capacitors 320 are charged.

When the generator 204 ceases operation, such as at shut of off the machine, each capacitor 320 momentarily remains energized, and the two halves of the filter capacitance system 600 act in isolation, i.e., the voltage at the node tapped to capacitor 349 does not change. During a brief interval after the generator 204 ceases operation, these capacitors 320 discharge through the resistor grid 214 (FIG. 5) at a rate that is related to the magnitude of the grid resistance and the capacitance values of each capacitor 320. As the discharge occurs, the voltage across the voltage transducer 314 is reduced from V to essentially zero.

If the resistance value of the resistor grid 214 were quite accurately known, it might be possible to assess the state of the capacitors 320 using standard methods. In practice, however, the resistance value of the first resistor grid 214 has proven difficult to estimate with the necessary accuracy, thwarting attempts to use discharge timing to analyze the capacitors 320.

However, in an exemplary use of the disclosed principles, the capacitance value of the capacitors 320 is calculated without knowledge of the resistance of the first resistor grid. In particular, the DC link voltage is processed to create a capacitance-related resistance-independent value that is used to identify changes in the capacitors 320. In an embodiment, the capacitance-related resistance-independent value is a voltage window integral of the DC link discharge current between defined voltage points.

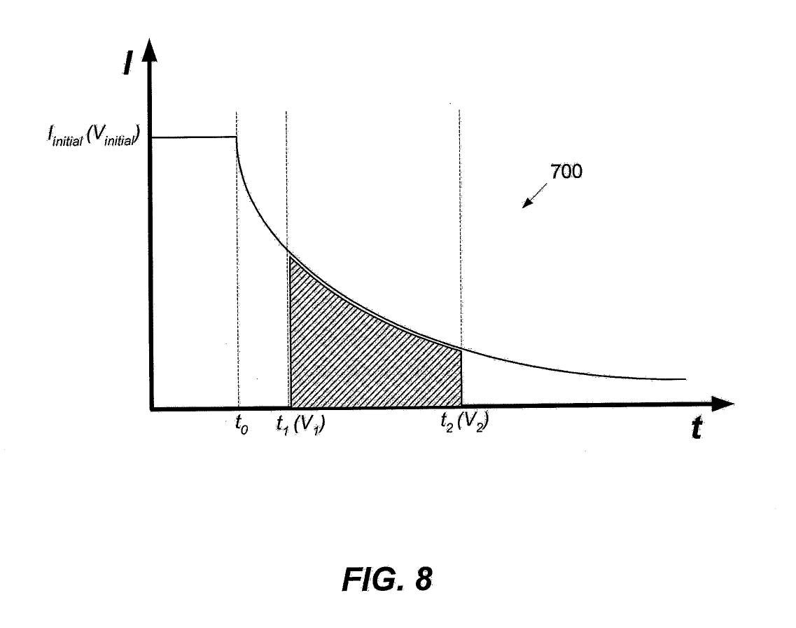

FIG. 8 is a timing diagram showing the discharge current curve 700 of the inverter capacitance system 600 of FIG. 7 as a function of time. As can be seen, the generator 204 ceases operation at a point t₀, while the DC link voltage is at a value V_{INITIAL}. After this point in time, the DC link voltage decays exponentially. Between voltage V₁ (at time t₁) and voltage V₂ (at time t₂) a series of discharge current measurements is taken in regular time increments. This series of current measurements is then used to create an integral of the DC link discharge current between voltage V₁ and voltage V₂, corresponding to the area of plot region 701. This capacitance-related resistance-independent value is then used as a fingerprint to later verify the state of the capacitors 320 of the filter capacitance system 600.

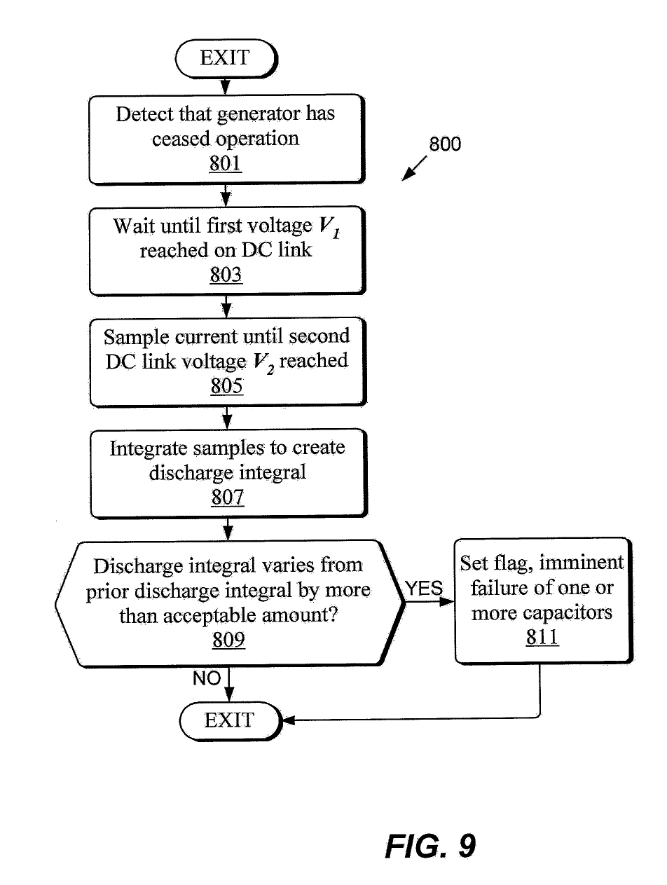

FIG. 9 is a flow chart illustrating a process 800 of filter capacitance diagnosis that is executed each time the machine is shut down. The process 800 is executed by the electronic controller 500 in an embodiment via the execution of computer-executable instructions, e.g., in machine language form or otherwise, read from a computer-readable medium, e.g., a magnetic or optical disc or other tangible medium. At stage 801 of the process 800, the electronic controller 500 detects that the generator 214 has ceased operation. This step may alternatively be achieved via messaging indicating that the machine is in shut-down mode.

In response to this detection, the electronic controller 500 waits at stage 803 until a first voltage V₁ is reached on the DC link 312 and then proceeds to stage 805. At stage 805, the controller takes a series of evenly spaced samples of the DC link current until a second voltage V₂ is reached on the DC link 312 voltage. The series of samples is then integrated over time in stage 807 to create a discharge integral, i.e., an approximation of the area under the voltage/time discharge curve between t₁ and t₂.

The discharge integral is compared at stage 809 with a prior discharge integral generated on the prior shut down cycle of the machine. In an embodiment, the discharge integral is compared with an average or other compilation of prior discharge integrals. These values may be stored locally or remotely, in any form convenient for use by the controller 500.

If at stage 809 it is determined that the discharge integral varies from the prior discharge integral by more than a predetermined acceptable amount such as a predetermined percentage (e.g., 5%), then the process 800 proceeds to stage 811. At stage 811, the controller 500 sets a diagnostic flag to indicate that failure of one or more capacitors 320 in the filter capacitance system 600 may be imminent. From stage 811, the process 800 exits. If it is determined at stage 809 that the discharge integral does not vary from the prior discharge integral by more than the predetermined percentage (or that there is not a prior discharge integral), then the process 800 exits from stage 809.

### INDUSTRIAL APPLICABILITY

The industrial applicability of the methods and systems for filter capacitance diagnosis as described herein should be readily appreciated from the foregoing discussion. The present disclosure may be included as part of an overall diagnostic scheme that monitors the operating condition of various circuit components in an electric drive system. That is, the diagnostic flags and/or alerts that are provided as a result of detecting a difference between expected and actual values may include the storage of diagnostic codes in memory that are later read out. Such diagnostic codes may take many different forms. For example, other operating data concerning the equipment and the time of the creation of the code or codes may also be stored and available for diagnosis. This arrangement is particularly suited for systems in which the number of available transducers is limited.

The disclosure, therefore, is applicable to many machines and many environments. One exemplary machine suited to the disclosure is an off-highway truck for use, e.g., in mines, construction sites, and quarries. Entities that use these off-highway trucks often sustain significant monetary losses for unscheduled down times when an off-highway truck is inoperable or is not operating at peak efficiency. Moreover, due to their size and complexity, off-highway trucks, particularly those adapted to use electric, hybrid, or direct series electric drive systems, traditionally require time-consuming processes to determine the source of a malfunction. Furthermore, it can often be difficult to quantify the degree to which such machines are functioning sub-optimally. Thus, this method and system that reduces the amount of time that an off-highway truck is inoperable or is operating sub-optimally can save significant expenditures.

Further, the methods and systems described above can be adapted to a large variety of machines and tasks. For example, other types of industrial machines, such as backhoe loaders, compactors, feller bunchers, forest machines, industrial loaders, skid steer loaders, wheel loaders and many other machines can benefit from the methods and systems described.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

We claim:

1. A method of inverter capacitance diagnosis for detecting an imminent failure of one or more inverter capacitors in an electric power supply system for a machine having a prime mover and a generator receiving power from the prime mover and producing electrical power that is processed and made available on a DC link, the method comprising:
detecting that the generator has ceased generating electrical power;
in response to detecting that the generator has ceased generating electrical power, waiting for a voltage of the DC link to reach a first predetermined voltage;
after the voltage of the DC link reaches the first predetermined voltage, taking a plurality of current samples on the DC link until a second predetermined voltage is reached on the DC link;
after the second predetermined voltage is reached on the DC link, integrating the plurality of current samples as a function of time to create a discharge integral;
comparing the discharge integral to a previously obtained discharge integral if a previously obtained discharge integral is available; and
setting a diagnostic flag to indicate an imminent failure of the one or more inverter capacitors if the discharge integral varies from the previously obtained discharge integral by more than a predetermined value.

2. The method of inverter capacitance diagnosis according to claim 1, wherein taking a plurality of current samples on the DC link comprises taking a plurality of evenly spaced current samples in time.

3. The method of inverter capacitance diagnosis according to claim 1, wherein the previously obtained discharge integral is the result of a prior diagnosis executed during a prior shut down cycle of the machine.

4. The method of inverter capacitance diagnosis according to claim 1, wherein comparing the discharge integral to a previously obtained discharge integral includes comparing the discharge integral to an average of previously obtained discharge integrals.

5. The method of inverter capacitance diagnosis according to claim 1, wherein setting the diagnostic flag to indicate an imminent failure of the one or more inverter capacitors includes setting the diagnostic flag if the discharge integral varies from the previously obtained discharge integral by more than a predetermined percentage.

6. The method of inverter capacitance diagnosis according to claim 1, wherein the discharge integral is deemed to not vary from the previously obtained discharge integral if there is no prior discharge integral available.

7. A computer-readable medium having thereon computer-executable instructions for performing a method of inverter capacitance diagnosis for detecting an imminent failure of one or more inverter capacitors in an electric power supply system for a machine having a prime mover and a generator receiving power from the prime mover and producing electrical power that is processed and made available on a DC link, the computer-executable instructions comprising:
instructions for detecting that the generator has ceased generating electrical power;
instructions for waiting for waiting for a voltage of the DC link to reach a first predetermined voltage in response to detecting that the generator has ceased generating electrical power;
instructions for taking a plurality of current samples on the DC link until a second predetermined voltage is reached on the DC link;
instructions for integrating the plurality of current samples as a function of time to create a discharge integral after the second predetermined voltage is reached on the DC link;
instructions for comparing the discharge integral to a previously obtained discharge integral if a previously obtained discharge integral is available; and
instructions for setting a diagnostic flag to indicate an imminent failure of the one or more inverter capacitors if the discharge integral varies from the previously obtained discharge integral by more than a predetermined value.

8. The computer-readable medium according to claim 7, wherein the instructions for taking a plurality of current samples on the DC link comprise instructions for taking a plurality of evenly spaced current samples in time.

9. The computer-readable medium according to claim 7, wherein the previously obtained discharge integral is the result of a prior diagnosis executed during a prior shut down cycle of the machine.

10. The computer-readable medium according to claim 7, wherein the instructions for comparing the discharge integral to a previously obtained discharge integral include instructions for comparing the discharge integral to an average of previously obtained discharge integrals.

11. The computer-readable medium according to claim 7, wherein the instructions for setting the diagnostic flag to indicate an imminent failure of the one or more inverter capacitors include the instructions for setting the diagnostic flag if the discharge integral varies from the previously obtained discharge integral by more than a predetermined percentage.

12. The computer-readable medium according to claim 7, wherein the discharge integral is deemed to not vary from the previously obtained discharge integral if there is no prior discharge integral available.

13. The computer-readable medium according to claim 7, wherein the one or more inverter capacitors comprise two inverter capacitors.

14. A controller for controlling one or more aspects of operation of an electric power supply system in a direct drive electric system having a prime mover and a generator receiving power from the prime mover and producing electrical power that is processed via one or more inverter capacitors and made available on a DC link, the controller embodying computer-executable instructions on a computer-readable medium to perform steps including:
detecting that the generator has ceased generating electrical power;
in response to detecting that the generator has ceased generating electrical power, waiting for a first predetermined voltage to be reached on the DC link;
after the predetermined voltage to be reached on the DC link, taking a plurality of current samples on the DC link until a second predetermined voltage is reached on the DC link;
after the second predetermined voltage is reached on the DC link, integrating the plurality of current samples as a function of time to create a discharge integral;
comparing the discharge integral to a previously obtained discharge integral if a previously obtained discharge integral is available; and
setting a diagnostic flag to indicate an imminent failure of the one or more inverter capacitors if the discharge integral varies from the previously obtained discharge integral by more than a predetermined value.

15. The controller according to claim 14, wherein taking a plurality of current samples on the DC link comprises taking a plurality of evenly spaced current samples.

16. The controller according to claim 14, wherein the previously obtained discharge integral is the result of a prior diagnosis executed during a prior shut down cycle of the machine.

17. The controller according to claim 14, wherein comparing the discharge integral to a previously obtained discharge integral includes comparing the discharge integral to an average of previously obtained discharge integrals.

18. The controller according to claim 14, wherein setting the diagnostic flag to indicate an imminent failure of the one or more inverter capacitors includes setting the diagnostic flag if the discharge integral varies from the previously obtained discharge integral by more than a predetermined percentage.

19. The controller according to claim 14, wherein the one or more inverter capacitors comprise two inverter capacitors.

20. The controller according to claim 14, wherein the discharge integral is deemed to not vary from the previously obtained discharge integral if there is no prior discharge integral available.
